(19) United States
(12) Patent Application Publication
(10) Pub. No.: US 2026/0314282 A1
(43) Pub. Date: Oct. 8, 2026

(54) SEMICONDUCTOR DEVICE AND METHOD FOR MANUFACTURING THE SAME

(71) Applicant: Magnachip Semiconductor, Ltd., Cheongju-si (KR)

(72) Inventor: Jun Hyun KIM, Gumi-si (KR)

(73) Assignee: Magnachip Semiconductor, Ltd., Cheongju-si (KR)

(21) Appl. No.: 19/368,215

(22) Filed: Oct. 24, 2025

(30) Foreign Application Priority Data
Apr. 8, 2025 (KR) 10-2025-0045482

(51) Int. Cl. H10P 30/40; H10D 64/01; H10D 64/27

(52) U.S. Cl. CPC H10P 30/40; H10D 64/027; H10D 64/513

(57) ABSTRACT

A method for manufacturing a semiconductor device includes forming a trench in a semiconductor substrate; forming an oxide film layer in the trench; selectively implanting an inert gas into an upper corner region of the oxide film layer through tilt ion implantation; and depositing a polysilicon layer on the oxide film layer to gap-fill the trench.

### CROSS-REFERENCE TO RELATED APPLICATION

This application claims the benefit under 35 U.S.C. § 119(a) of Korean Patent Application No. 10-2025-0045482, filed on Apr. 8, 2025, in the Korean Intellectual Property Office, the entire disclosure of which is incorporated herein by reference for all purposes.

### BACKGROUND

### 1. Field

The present disclosure relates to a method for manufacturing a semiconductor device in which a conductive material is uniformly deposited in a trench so as to prevent the formation of seams or voids, and to a semiconductor device manufactured thereby.

### 2. Description of the Background

A trench-type metal-oxide semiconductor field effect transistor (MOSFET) is employed in high-power semiconductor applications. A trench semiconductor device is a type of transistor in which a channel is formed vertically, and a gate is disposed within a trench that extends between a source and a drain.

In semiconductor devices, the internal structure of the trench may be used to achieve high-efficiency and high-performance power in MOSFETs. Accordingly, when depositing a conductive material, such as polysilicon, inside the trench, it may be desirable for the polysilicon to be deposited uniformly. Otherwise, a seam may form on the upper surface of the polysilicon, or a void may be formed inside the trench. Conventionally, such phenomena have been associated with the angle of the trench during formation.

The seam or void functions as a defect in the semiconductor device, thereby affecting the device profile or characteristics. As a result, the electrical characteristics and reliability of the semiconductor device are degraded.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method for manufacturing a semiconductor device includes forming a trench in a semiconductor substrate; forming an oxide film layer in the trench; selectively implanting an inert gas into an upper corner region of the oxide film layer through tilt ion implantation; and depositing a polysilicon layer on the oxide film layer to gap-fill the trench.

The method may further include performing a cleaning process after the implanting of the inert gas.

The cleaning process may include performing a first cleaning with a UD cleaning solution; and performing a second cleaning with a 1:19 Hafnium (HF) solution or a Buffered Oxide Etch (BOE) solution.

The method may further include performing a thermal process on the gap-filled polysilicon layer.

The thermal process may be performed at a temperature in a range of 900° C. to 1050° C.

The inert gas may be argon (Ar) ions.

The tilt ion implanting may further include implanting the inert gas while tilting and twisting a platen positioned under the semiconductor substrate at predetermined angles, and repeatedly implanting the inert gas while rotating the platen at predetermined angles.

The trench may have an angle of 89° to 89.5° when the trench is formed.

The oxide film layer may be formed to have a thickness of 600 nm to 800 nm.

The tilting may have an angle of 30° to 40°, the twisting may have an angle of 30° to 50°, and a dose of the inert gas may be 1.0E14 to 2.0E14.

In another general aspect, a method for manufacturing a semiconductor device includes forming a trench in a semiconductor substrate; forming an oxide film layer in the trench; tilting a platen positioned under the semiconductor substrate and selectively implanting an inert gas into an upper corner region of the oxide film layer using an ion implanter; and depositing a polysilicon layer on the oxide film layer to gap-fill the trench.

The inert gas may include argon (Ar) ions.

The tilting of the platen positioned under the semiconductor substrate may include tilting, twisting, and rotating the platen at predetermined angles with respect to the upper corner region of the trench.

The inert gas may be implanted at an energy level range of 200 KeV to 400 KeV, with the platen tilted at an angle of 30° to 40° and twisted at an angle of 30° to 50°, while the platen positioned under the semiconductor substrate is rotated in 90° increments, to achieve a total implementation dose of 1.0E14 to 2.0E14.

The method may further include performing a thermal process at a predetermined temperature after forming the polysilicon layer.

In another general aspect, a semiconductor device include a semiconductor substrate; a trench disposed in the semiconductor substrate; an oxide film layer disposed along an upper surface of the semiconductor substrate and an inner wall of the trench; and a polysilicon layer disposed to gap-fill the trench, wherein an angle of an upper corner region of the oxide film layer is 85° or less.

The trench may have an angle of 89° to 89.5° when the trench is formed.

The upper corner region of the oxide film layer may be formed by ion implantation of an inert gas.

The inert gas may be argon (Ar) ions.

The oxide film layer may have a thickness of 600 nm to 800 nm.

Other features and aspects will be apparent from the following detailed description, the drawings, and the claims.

### BRIEF DESCRIPTION OF DRAWINGS

FIG. 1A illustrates a semiconductor device that may include a semiconductor layer and an epitaxial layer formed in a semiconductor substrate according to the prior art.

FIG. 1B illustrates that a polysilicon layer is formed on the sacrificial oxide layer according to the prior art.

FIG. 1C illustrates that voids are formed in the polysilicon layer inside the trenches according to the prior art.

FIG. 1D illustrates that voids remain in the polysilicon layer according to the prior art.

FIG. 2A illustrates a semiconductor device that may include a semiconductor layer and an epitaxial layer formed in a semiconductor substrate according to an embodiment of the present disclosure.

FIG. 2B illustrates that an oxide film layer is formed on an inner wall of the trench according to an embodiment of the present disclosure.

FIG. 2C illustrates an implantation process according to an embodiment of the present disclosure.

FIG. 2D illustrates an implantation process according to an embodiment of the present disclosure.

FIG. 2E illustrates forming a polysilicon layer in the trench according to an embodiment of the present disclosure.

FIG. 3A is an SEM cross-sectional image of a trench according to the prior art.

FIG. 3B is an SEM cross-sectional image of a trench according to an embodiment of the present disclosure.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

Hereinafter, the present disclosure will be described in more detail based on embodiments illustrated in the drawings. The following description of the prior art and the present disclosure focuses on a trench region of a semiconductor substrate, since the technical feature lies in a method of uniformly forming a polysilicon layer inside a trench.

An object of the present disclosure is to provide a method for manufacturing a semiconductor device in which seams or voids are not formed during fabrication.

Another object of the present disclosure is to provide a method of uniformly depositing a conductive material inside a trench, independent of the trench angle.

The technical problems addressed by the present disclosure are not limited to those described above, and other technical problems not explicitly mentioned will be readily understood by those skilled in the art from the following description.

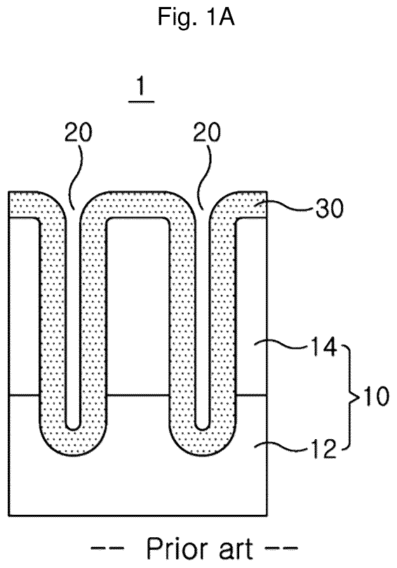

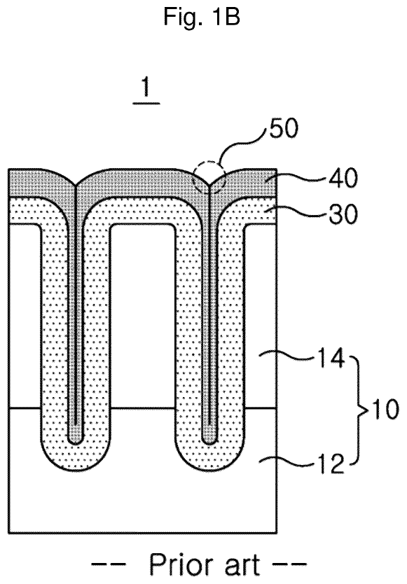

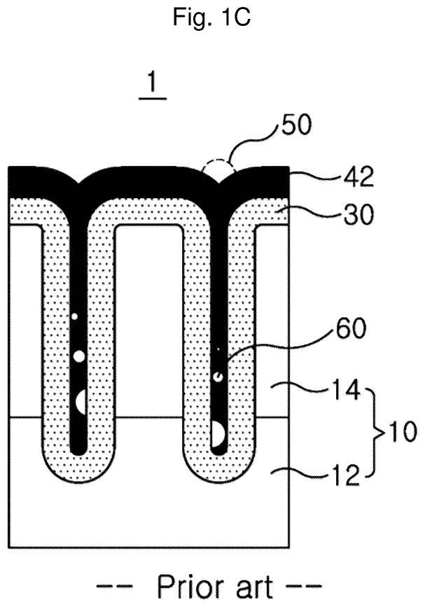

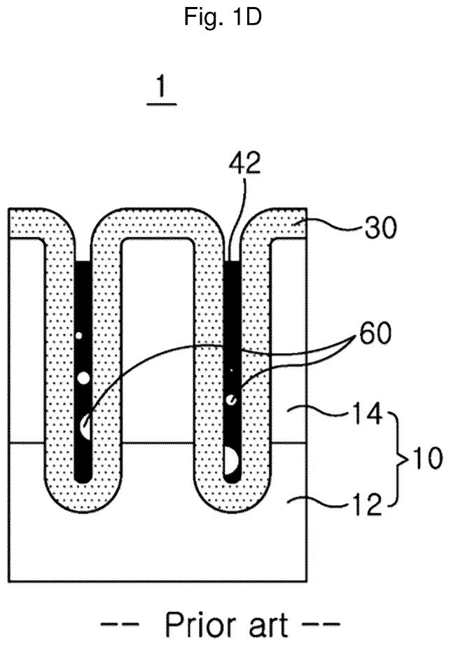

FIGS. 1A to 1D are diagrams illustrating a process for manufacturing a semiconductor device according to the prior art.

In FIG. 1A, a semiconductor device 1 may include a semiconductor layer 12 and an epitaxial layer 14 formed in a semiconductor substrate 10. The semiconductor layer 12 may be a highly doped semiconductor layer of a first conductivity type (N), and the epitaxial layer 14 may be a lightly doped epitaxial layer of the first conductivity type (N). The epitaxial layer 14 may also be referred to as a lightly doped drift region of the first conductivity type (N).

In FIG. 1A, the semiconductor device 1 includes a plurality of trenches 20. The trenches 20 may be formed to a predetermined depth from an upper surface of the semiconductor substrate 10. The trenches 20 are formed with a trench angle of 89° to 89.5°. At this time, damage such as etch damage may occur inside the trenches 20 due to an etching process performed to form the trenches. In order to remove such damage, a sacrificial oxide layer 30 may be grown. Such damage may be removed through the process of growing the sacrificial oxide layer 30.

In FIG. 1A, the sacrificial oxide layer 30 is formed in the trenches 20. The sacrificial oxide layer 30 may be formed using an oxidation method or a low pressure chemical vapor deposition (LPCVD) method. Formation of the sacrificial oxide layer 30 reduces the width of the trenches 20.

In FIG. 1B, a polysilicon layer 40 is formed on the sacrificial oxide layer 30. The polysilicon layer 40 completely fills the trenches 20. The polysilicon layer 40 may be doped or undoped.

As shown in FIG. 1B, when the polysilicon layer 40 is deposited, a seam 50 is formed on the upper surface of the polysilicon layer 40 located at the top side of the trenches 20, such that a central portion between adjacent trenches becomes recessed. In this state, when an impurity diffusion process is performed, voids 60 are formed in the polysilicon layer 42 inside the trenches, as shown in FIG. 1C. This occurs because the polysilicon layer is not deposited uniformly throughout the trench during the deposition process. Furthermore, as shown in FIG. 1D, even after a subsequent process of partially removing the polysilicon layer 42 inside the trenches 20, the voids 60 remain in the polysilicon layer 42 without being eliminated.

The foregoing problem frequently arises when polysilicon is deposited with the trench angle set to 89° to 89.5° during semiconductor device fabrication. In other words, due to the trench angle, the polysilicon cannot be deposited uniformly inside the trenches, resulting in seams and voids, as illustrated in FIGS. 1A to 1D. Attempts have been made to address this issue by changing the trench angle and then growing or depositing an oxide film layer; however, such approaches have not provided a fundamental solution. For example, changing the trench angle creates additional difficulty because certain steps in the semiconductor device fabrication process must be modified.

The present disclosure provides a method for manufacturing a semiconductor device in which an oxide film layer is first formed in a trench of a semiconductor substrate, and an upper corner region of the oxide film layer is then removed, allowing a polysilicon layer to be naturally deposited into the trench. In this way, seams and voids inside the trench can be prevented while maintaining the trench angle at 89° to 89.5°, as in the prior art.

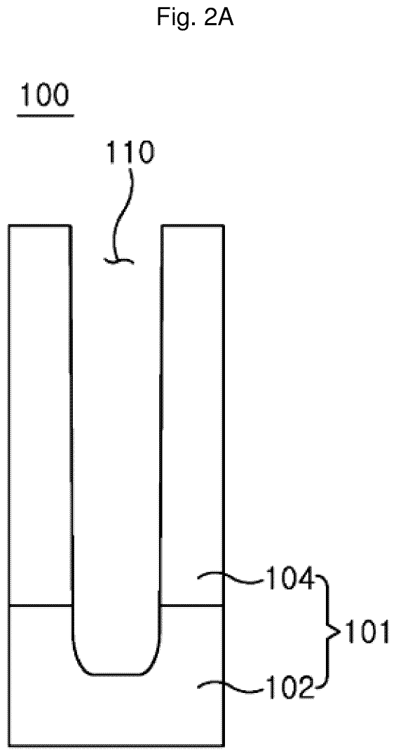

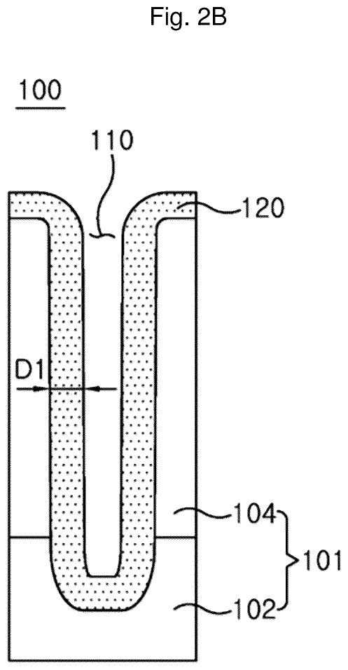

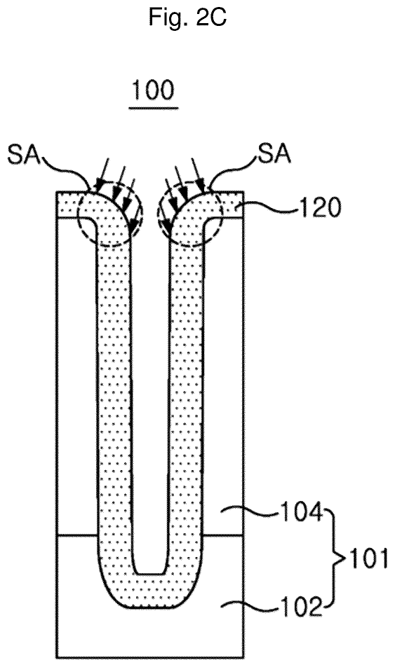

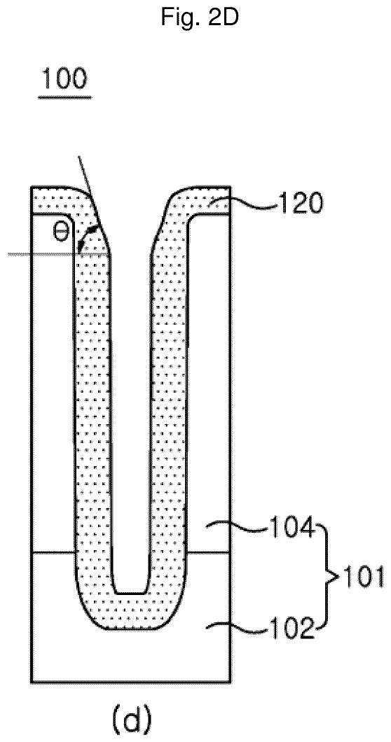

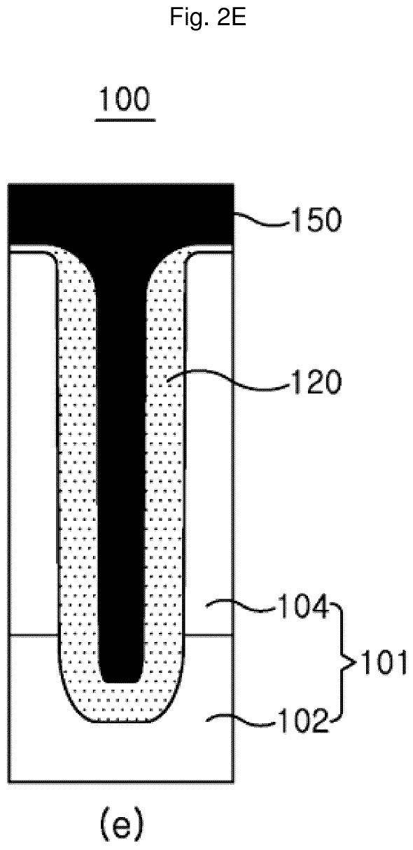

FIGS. 2A to 2E are diagrams illustrating a manufacturing process of a semiconductor device according to an embodiment of the present disclosure.

In FIG. 2A, a semiconductor device 100 may include a semiconductor layer 102 and an epitaxial layer 104 formed in a semiconductor substrate 101. The semiconductor layer 102 may be a highly doped semiconductor layer having an N-type dopant, and the epitaxial layer 104 may be a lightly doped epitaxial layer having fewer N-type dopants than the semiconductor layer 102.

The semiconductor device 100 according to one embodiment of the present disclosure includes a trench 110 formed in the semiconductor substrate 101. The trench 110 may be formed to a predetermined depth from an upper surface of the semiconductor substrate 101. Although only one trench is illustrated in FIG. 2A, in practice, a plurality of trenches may be formed at regular intervals in a horizontal direction of the semiconductor substrate 101. The trench 110 may be formed through a trench etching process so as to have a trench angle of 89° to 89.5° with respect to a vertical direction of the semiconductor substrate 101. This is the same trench angle as that used in manufacturing semiconductor devices according to the prior art. Accordingly, the changing of the trench angle may be avoided, and no additional processes are used to modify the trench angle.

In FIG. 2B, after the trench 110 is formed in the semiconductor substrate 101, an oxide film layer 120 is formed on an inner wall of the trench 110 and on an upper surface of the semiconductor substrate 101. The oxide film layer 120 may be formed by growing an oxide or by depositing tetraethyl orthosilicate (TEOS). In this case, the oxide film layer 120 may be formed to have a thickness D1 of about 600 nm to 800 nm.

After the oxide film layer 120 is formed, as shown in FIG. 2B, an oxidation process is performed on the oxide film layer 120. When the oxide film layer 120 is formed by deposition of TEOS, an oxidation process may be performed at about 950 to 1050° C. to a depth of about 500 Å in order to densify the oxide film layer 120.

FIG. 2C illustrates an implantation process according to an embodiment of the present disclosure. The implantation process involves selectively removing only an upper corner region SA of the oxide film layer 120. According to the embodiment, the implantation process may be performed by injecting an inert gas, such as argon (Ar) ions, toward the upper corner region SA of the oxide film layer 120 under specific conditions. An inert gas is used because, even if ions remain in the oxide film layer 120, they do not exhibit electrical characteristics and therefore do not affect the performance of the semiconductor device 100.

The injection conditions of the argon ions may be as follows. The semiconductor substrate 101 is placed on platen equipment (not shown). Using the platen option, the substrate is tilted at about 30° to 40° and twisted at about 30° to 50°, with an overall dose of 1.0E14 to 2.0E14 at an energy level of 200 keV to 400 keV. In addition, the platen option is set so that the substrate is rotated four times in 90° increments while argon ions are injected, allowing the upper corner region SA of the oxide film layer 120 to be evenly removed. The tilt and twist angles may be adjusted according to the trench angle of the substrate and the thickness of the oxide film layer 120 formed along the inner wall of the trench 110.

According to an embodiment of the present disclosure, when the implantation process is performed by tilting and twisting the argon ion injection at predetermined angles to remove the upper corner region SA of the oxide film layer 120, penetration of argon ions into the lower region of the trench 110 can be prevented, thereby minimizing damage to the oxide film layer in that region.

According to an embodiment of the present disclosure, the oxide film layer 120 exhibits different etching rates between a region implanted with argon ions and a region not implanted with argon ions. For example, the region implanted with argon ions etches faster than the non-implanted region, thereby enabling effective removal of the implanted region. In the embodiment, the etching rate of the argon ion-implanted region is approximately 3.5 to 4 times faster than that of the non-implanted region.

FIG. 2D is a diagram after the above-described implantation process has been performed. As shown, the upper corner region SA of the oxide film layer 120 is removed to a greater extent than the other regions. The angle θ of the upper corner region SA may be 85° or less.

As illustrated in FIG. 2D, a cleaning process may be further performed after the completion of the implantation process. The cleaning process is carried out in a state in which the upper corner region SA of the oxide film layer 120 has been removed by the implantation process. The cleaning process may include first cleaning with a UD cleaning solution, followed by cleaning with 1:19 Hafnium (HF) for about 120 to 150 seconds, or alternatively cleaning with Buffered Oxide Etch (BOE) for about 60 to 120 seconds. Here, the UD cleaning solution may, for example, be a cleaning performed by mixing a U-cleaning solution that is cleaned using a mixture of NH₄OH+H₂O₂+H₂O and a D-cleaning solution that is cleaned using a mixture of HCl+H₂O₂+H₂O.

FIG. 2E illustrates a process of forming a polysilicon layer 150 in the trench. According to an embodiment of the present disclosure, since the upper corner region SA of the oxide film layer 120 has been removed more than other regions, the polysilicon layer 150 can be uniformly deposited inside the trench when the polysilicon layer 150 is formed.

Accordingly, as shown in FIG. 2E, no seams are formed on the upper surface of the polysilicon layer 150, and no voids are formed inside the trench.

According to an embodiment of the present disclosure, the polysilicon layer 150 may be doped or undoped. For example, undoped polysilicon may be deposited by a low pressure chemical vapor deposition (LPCVD) method using SiH₄. In the case of doped polysilicon, LPCVD deposition may be performed using a gas mixture in which PH₃, PCls, BCl₃, or B₂H₆ is mixed with SiH₄.

Meanwhile, according to an embodiment of the present disclosure, a thermal process may further be performed. After forming the polysilicon layer 150, a thermal process may be performed at a temperature range of about 900° C. to 1050° C.

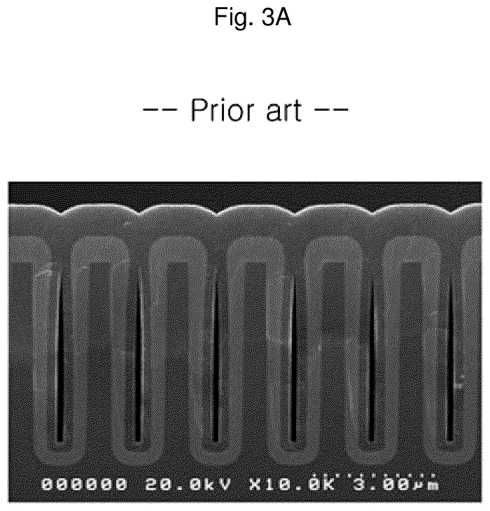

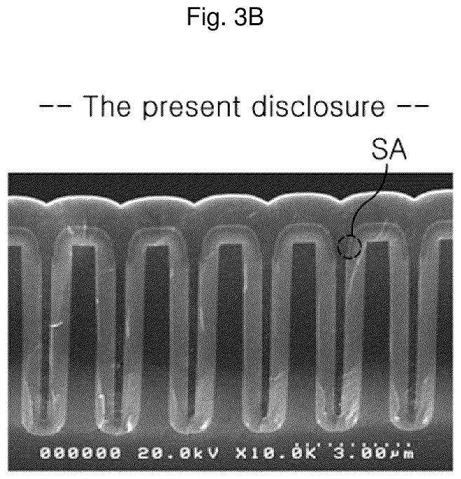

FIGS. 3A and 3B show SEM cross-sectional images of a trench according to the prior art and an embodiment of the present disclosure, respectively.

As shown in FIGS. 3A and 3B, the upper corner region SA of the oxide film layer in the present disclosure is removed to a greater extent than in the prior art. Accordingly, in the prior art SEM image FIG. 3A, voids are observed inside the trench, whereas in the SEM image FIG. 3B, a polysilicon layer is uniformly deposited without void formation in the trench.

Thus, the present disclosure provides a structure in which, after an oxide film layer is formed in a trench of a semiconductor substrate, a corner region of the oxide film layer is removed by implanting an inert gas. This allows a polysilicon layer to be uniformly deposited inside the trench in a subsequent process, thereby enabling fabrication of a semiconductor device without seams on the upper surface of the polysilicon layer or voids inside the trench.

Table 1 below shows the removal ratio of the oxide film layer according to the implantation energy and dose of argon ions.

TABLE 1

| Energy(KeV) | Dose | Etch rate(Å) | Removal ratio |
|---|---|---|---|
| 40 | 1.00E+15 | 566 | 2.60 |
| 60 | 1.00E+15 | 703 | 3.22 |
| 60 | 2.00E+14 | 586 | 2.69 |
| 120 | 1.00E+15 | 842 | 3.86 |
| 120 | 4.00E+15 | 848 | 3.89 |
| 120 | 6.00E+15 | 859 | 3.94 |
| 120 | 8.00E+15 | 877 | 4.02 |
| 200 | 2.00E+14 | 823 | 3.78 |

As shown in Table 1, the highest removal rate is achieved when the argon ion energy is 120 KeV, the dose is 8.00E+15, and the etch rate is 877 Å. This, however, is only one example. The energy, dose, and etch rate conditions of the argon ions may be varied to obtain an appropriate removal ratio depending on factors such as the performance of the ion implanter, the trench angle, and the oxide film layer thickness.

According to the present disclosure, after an oxide film layer is formed in a trench, an inert gas is implanted into an upper corner region of the trench, and that region is partially removed. As a result, when a polysilicon layer is formed in a subsequent process, a semiconductor device can be fabricated without seams or voids inside the trench. Accordingly, the present disclosure can prevent problems of deterioration in the electrical characteristics or reliability of the semiconductor device.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method for manufacturing a semiconductor device, comprising:
forming a trench in a semiconductor substrate;
forming an oxide film layer in the trench;
selectively implanting an inert gas into an upper corner region of the oxide film layer through tilt ion implantation; and
depositing a polysilicon layer on the oxide film layer to gap-fill the trench.

2. The method of claim 1, further comprising:
performing a cleaning process after the implanting of the inert gas.

3. The method of claim 2,
wherein the cleaning process comprises:
performing a first cleaning with a UD cleaning solution; and
performing a second cleaning with a 1:19 Hafnium (HF) solution or a Buffered Oxide Etch (BOE) solution.

4. The method of claim 1, further comprising:
performing a thermal process on the gap-filled polysilicon layer.

5. The method of claim 4,
wherein the thermal process is performed at a temperature in a range of 900° C. to 1050° C.

6. The method of claim 1,
wherein the inert gas is argon (Ar) ions.

7. The method of claim 1,
wherein the tilt ion implanting further comprises:
implanting the inert gas while tilting and twisting a platen positioned under the semiconductor substrate at predetermined angles, and repeatedly implanting the inert gas while rotating the platen at predetermined angles.

8. The method of claim 1,
wherein the trench has an angle of 89° to 89.5° when the trench is formed.

9. The method of claim 1,
wherein the oxide film layer is formed to have a thickness of 600 nm to 800 nm.

10. The method of claim 7,
wherein the tilting has an angle of 30° to 40°, the twisting has an angle of 30° to 50°, and a dose of the inert gas is 1.0E14 to 2.0E14.

11. A method for manufacturing a semiconductor device, comprising:
forming a trench in a semiconductor substrate;
forming an oxide film layer in the trench;
tilting a platen positioned under the semiconductor substrate and selectively implanting an inert gas into an upper corner region of the oxide film layer using an ion implanter; and
depositing a polysilicon layer on the oxide film layer to gap-fill the trench.

12. The method of claim 11,
wherein the inert gas comprises argon (Ar) ions.

13. The method of claim 11,
wherein the tilting of the platen positioned under the semiconductor substrate comprises:
tilting, twisting, and rotating the platen at predetermined angles with respect to the upper corner region of the trench.

14. The method of claim 13,
wherein the inert gas is implanted at an energy level range of 200 KeV to 400 KeV, with the platen tilted at an angle of 30° to 40° and twisted at an angle of 30° to 50°, while the platen positioned under the semiconductor substrate is rotated in 90° increments, to achieve a total implementation dose of 1.0E14 to 2.0E14.

15. The method of claim 11, further comprising:
performing a thermal process at a predetermined temperature after forming the polysilicon layer.

16. A semiconductor device, comprising:
a semiconductor substrate;
a trench disposed in the semiconductor substrate;
an oxide film layer disposed along an upper surface of the semiconductor substrate and an inner wall of the trench; and
a polysilicon layer disposed to gap-fill the trench,
wherein an angle of an upper corner region of the oxide film layer is 85° or less.

17. The semiconductor device of claim 16,
wherein the trench has an angle of 89° to 89.5° when the trench is formed.

18. The semiconductor device of claim 16,
wherein the upper corner region of the oxide film layer is formed by ion implantation of an inert gas.

19. The semiconductor device of claim 18,
wherein the inert gas is argon (Ar) ions.

20. The semiconductor device of claim 16,
wherein the oxide film layer has a thickness of 600 nm to 800 nm.
